(19) United States
(12) Patent Application Publication
(10) Pub. No.: US 2026/0012159 A1
(43) Pub. Date: Jan. 8, 2026

(54) Low-Pass Filter Circuitry

(71) Applicant: Apple Inc., Cupertino, CA (US)

(72) Inventor: Milad Darvishi, San Diego, CA (US)

(21) Appl. No.: 19/061,706

(22) Filed: Feb. 24, 2025

Related U.S. Application Data
(60) Provisional application No. 63/667,925, filed on Jul. 5, 2024.

(51) Int. Cl. H03H 11/12

(52) U.S. Cl. CPC H03H 11/1204

(57) ABSTRACT

Filter circuitry is provided that includes a resistor having a first terminal coupled to an input of the filter circuitry and having a second terminal coupled to an output of the filter circuitry, a capacitor having a first terminal coupled to the second terminal of the resistor and having a second terminal coupled to a power supply line, and a transistor coupled to the first terminal of the resistor or the second terminal of the resistor. The transistor can be coupled to a bias current and additional capacitors. A switch can be coupled between the transistor and the first terminal of the resistor. A switch can be coupled between the transistor and the second terminal of the resistor. The filter circuitry can be configured to provide a low-pass filter response with a reduced in-band droop when the switch and the bias current are activated.

This application claims the benefit of U.S. Provisional Patent Application No. 63/667,925, filed Jul. 5, 2024, which is hereby incorporated by reference herein in its entirety.

### FIELD

This disclosure relates generally to electronic circuits, including electronic circuits with filters.

### BACKGROUND

Electronic circuits can include filters such as low-pass filters. A low-pass filter is a circuit that passes signals having frequencies lower than a certain cutoff frequency while attenuating or rejecting signals having frequencies greater than the cutoff frequency. An analog low-pass filter can be implemented as a RC filter that includes a series resistor (R) and a shunt capacitor (C).

Conventional RC filters, however, exhibit a tight tradeoff between in-band droop and out-of-band rejection. In-band droop can refer to an undesirable amount of signal attenuation before the cutoff frequency. Out-of-band rejection can refer to a desired amount of signal rejection at some frequency greater than the cutoff frequency. A tight tradeoff would thus degrade the in-band droop when increasing the out-of-band rejection, and vice versa. It is within such context that the embodiments herein arise.

### SUMMARY

An aspect of the disclosure provides filter circuitry that includes a resistor having a first terminal coupled to an input of the filter circuitry and having a second terminal coupled to an output of the filter circuitry, a first capacitor having a first terminal coupled to the second terminal of the resistor and having a second terminal coupled to a first power supply line, and a transistor coupled to the first terminal of the resistor or the second terminal of the resistor. The filter circuitry can further include a switch coupled between the second terminal of the resistor and a gate terminal of the transistor, a second capacitor having a first terminal coupled to the gate terminal of the transistor and having a second terminal coupled to a source-drain terminal of the transistor, a third capacitor having a first terminal coupled to the source-drain terminal of the transistor and having a second terminal coupled to the first power supply line, and a current source coupled between the source-drain terminal of the transistor and a second power supply line different than the first power supply line. The current source can be selectively deactivated when the filter circuitry is operating in a first range of frequencies and activated when the filter circuitry is operating in a second range of frequencies different than the first range of frequencies.

An aspect of the disclosure provides circuitry that includes a resistor having a first terminal coupled to an input terminal and having a second terminal coupled to an output terminal, a first capacitor having a first terminal coupled to the second terminal of the resistor and having a second terminal coupled to a first power supply line, and a transistor coupled to the second terminal of the resistor. The circuitry can further include a switch coupled between the second terminal of the resistor and a gate terminal of the transistor, the circuitry being configured to provide a low-pass filter response with a first in-band droop when the switch is deactivated and a low-pass filter response with a second in-band droop, less than the first in-band droop, when the switch is activated. The circuitry can further include a second capacitor coupled between a gate terminal and a source-drain terminal of the transistor, a third capacitor coupled between the source-drain terminal of the transistor and the first power supply line, and a current source coupled between the source-drain terminal of the transistor and a second power supply line different than the first power supply line.

An aspect of the disclosure provides circuitry that includes a first resistor having a first terminal coupled to an input terminal and having a second terminal, a second resistor having a first terminal coupled to the second terminal of the first resistor and having a second terminal coupled to an output terminal, a first capacitor having a first terminal coupled to the second terminal of the second resistor and having a second terminal coupled to a power supply line, and a transistor coupled to a node disposed between the first and second resistors. The circuitry can further include a second capacitor coupled between a gate terminal and a source-drain terminal of the transistor, a third capacitor coupled between the source-drain terminal of the transistor and the power supply line, and a current sink coupled between the source-drain terminal of the transistor and the power supply line. The circuitry can be configured to provide a low-pass filter response with a first in-band droop when the current sink is deactivated and a low-pass filter response with a second in-band droop, less than the first in-band droop, when the current sink is activated.

### BRIEF DESCRIPTION OF THE DRAWINGS

FIG. 1 is a diagram of illustrative low-pass filter circuitry in accordance with some embodiments.

FIG. 2 is a diagram showing various low-pass filter frequency responses.

FIG. 3 is a circuit diagram of illustrative low-pass filter circuitry with reduced in-band droop in accordance with some embodiments.

FIG. 4 is a state diagram showing how the low-pass filter circuitry of the type shown in FIG. 3 can be operable in multiple modes in accordance with some embodiments.

FIG. 5 is a circuit diagram showing another implementation of illustrative low-pass filter circuitry with reduced in-band droop in accordance with some embodiments.

FIG. 6 is a circuit diagram of illustrative switchable low-pass filter circuitry in accordance with some embodiments.

FIG. 7 is a block diagram of illustrative wireless circuitry that can be provided with filter circuitry in accordance with some embodiments.

FIG. 8 is a circuit diagram showing illustrative wireless circuitry having filter circuitry coupled between a data converter and a mixer in accordance with some embodiments.

### DETAILED DESCRIPTION

Electronic circuits can include filter circuitry. Filter circuitry such as low-pass filter (LPF) circuitry is provided that includes one or more passive components, at least one transistor, and one or more switchable components. The low-pass filter circuitry can be selectively enabled (switched into use) or disabled when not needed. The low-pass filter circuitry can provide reduced in-band droop without trading off out-of-band rejection. The low-pass filter circuitry can further provide high-pass filtering of any associated noise. In some embodiments, the low-pass filter circuitry can be incorporated as part of wireless communications circuitry within an electronic device. For example, the low-pass filter circuitry can be included as part of a transmit signal path of the wireless communications circuitry. In general, the low-pass filter circuitry can be included as part of a transmit signal path, a receive signal path, or other data paths on one or more integrated circuits.

An electronic device that includes the low-pass filter circuitry can be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

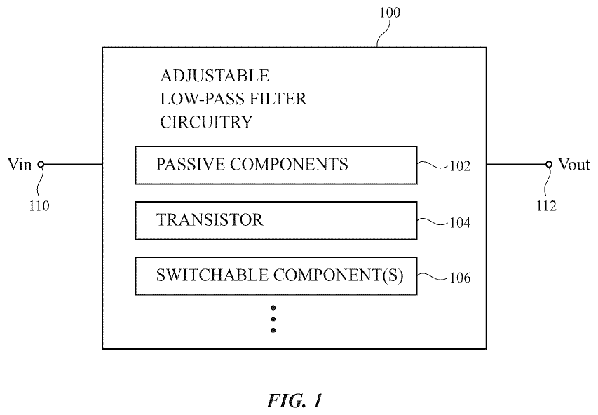

FIG. 1 is a diagram of illustrative low-pass filter circuitry such as low-pass filter (LPF) circuitry 100 in accordance with some embodiments. As shown in FIG. 1, low-pass filter circuitry 100 can have an input terminal 110 (e.g., an input port on which an input signal or voltage Vin is provided), an output terminal (e.g., an output port on which an output signal or voltage Vout is provided), passive components such as passive components 102, one or more transistors such as transistor 104, one or more switchable components such as switchable component(s) 106, and optionally other electrical components. Switchable components 106 can be controlled to selectively activate (switch into use) or deactivate (switch out of use) one or more portions of low-pass filter circuitry 100. Operated in this way, low-pass filter circuitry 100 is thus sometimes referred to herein as an “adjustable” low-pass filter or a “switchable” low-pass filter. In general, the term “low-pass filter” can refer to and be defined herein as an electronic circuit for selectively passing signals having frequencies less than a cutoff frequency of the filter and attenuating/rejecting signals having frequencies greater than the cutoff frequency. A low-pass filter's cutoff frequency is sometimes also referred to as a corner frequency, a break frequency, or a −3 dB frequency (e.g., a frequency at which the output signal amplitude is reduced by 3 decibels).

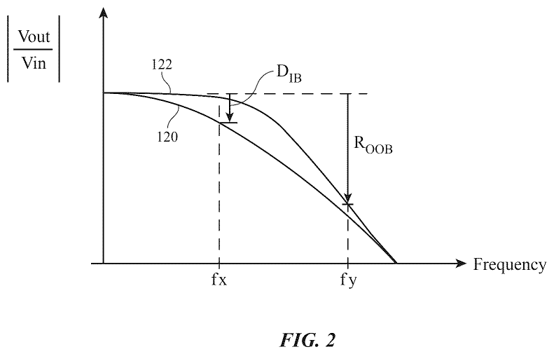

FIG. 2 is a diagram showing various low-pass filter frequency responses. In particular, FIG. 2 plots the magnitude of the output voltage Vout divided by the input voltage Vin as a function of frequency. As shown in FIG. 2, curve 120 may represent a filter response of a conventional RC low-pass filter that includes only a series resistor (R) coupled to a shunt capacitor (C). A simple RC filter may exhibit a tight tradeoff between out-of-band rejection and in-band droop. In-band droop can refer to and be defined herein an amount of signal attenuation at or before a cutoff frequency (see frequency fx in the example of FIG. 2). Out-of-band rejection can refer to a desired amount of signal rejection at some frequency greater than the cutoff frequency (see frequency fy in FIG. 2, where fy is greater than fx). In the example of FIG. 2, to provide a target out-of-band rejection amount RooB at frequency fy, the RC filter response 120 may suffer from an in-band droop amount DIB at the cutoff frequency that is more than the target 3 dB drop. Such in-band droop can negatively impact the performance of the RC filter and any electronic circuit that includes such filter.

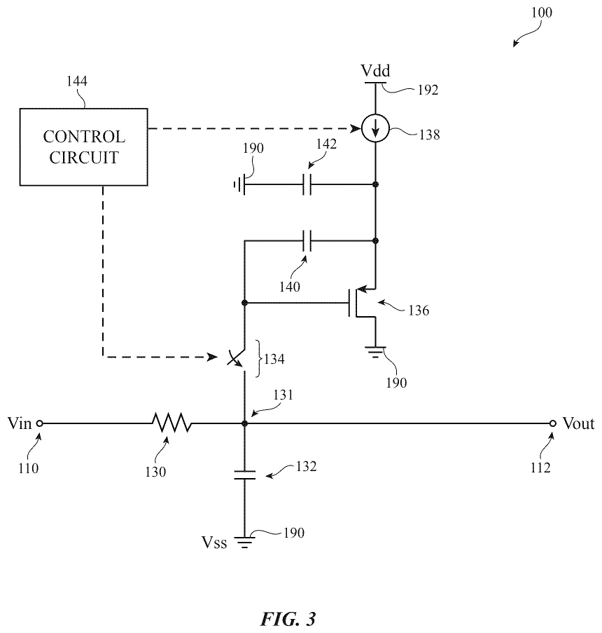

In accordance with an embodiment, low-pass filter circuitry 100 is provided that exhibits a filter response such as improved low-pass filter response 122. As shown in FIG. 2, low-pass filter response 122 is technically advantageous over the conventional RC filter response 120 since filter response 122 can simultaneously provide the target out-of-band rejection R_{OOB} at frequency fy while exhibiting substantially reduced in-band droop, relative to in-band droop D_{IB} for the conventional RC filter, at cutoff frequency fx. Various implementations of low-pass filter circuitry 100 that can provide such improved low-pass filter response 122 are described in connection with FIGS. 3-8.

FIG. 3 is a circuit diagram of illustrative low-pass filter circuitry 100 that can provide reduced in-band droop. As shown in FIG. 3, low-pass filter circuitry 100 may include a resistor such as series resistor 130, a capacitor such as shunt capacitor 132, a transistor 136, capacitors 140 and 142, a current source such as current source 138, and a switch such as switch 134. Resistor 130 may have a first terminal coupled to input terminal 110 (sometimes referred to as a filter input terminal) and a second terminal coupled to output terminal 112. Capacitor 132 may have a first terminal coupled to output terminal 112 (sometimes referred to as a filter output terminal) and a second terminal coupled to a ground power supply line 190 (e.g., a ground line on which ground power supply voltage Vss is provided). Filter circuitry 100 having at least one active component such as transistor 136 is sometimes referred to as an “active” filter.

Transistor 136 may be a p-type transistor such as a p-channel metal-oxide-semiconductor (PMOS) transistor having a drain terminal coupled to ground 190, a source terminal coupled to current source 138, and a gate terminal selectively coupled, via switch 134, to a node 131 that is disposed between series resistor 130 and shunt capacitor 132. Node 131 may be shorted to the filter output terminal 112. The terms “source” and “drain” are sometimes used interchangeably when referring to current-conducting terminals of a metal-oxide-semiconductor transistor. The source and drain terminals are therefore sometimes referred to as “source-drain” terminals (e.g., a transistor has a gate terminal, a first source-drain terminal, and a second source-drain terminal).

The term “activate” with respect to a switch (or transistor) may refer to or be defined herein as an action that places the switch in an “on” or low-impedance state such that the two terminals of the switch are electrically connected to conduct current. Activating a switch can sometimes be referred to as turning on or closing a switch. The term “deactivate” with respect to a switch (or transistor) may refer to or be defined herein as an action that places the switch in an “off” or high-impedance state such that the two terminals of the switch/transistor are electrically disconnected with minimal leakage current. Deactivating a switch can sometimes be referred to as turning off or opening a switch.

Capacitor 140 may have a first terminal coupled to the gate terminal of transistor 136 and a second terminal coupled to the source terminal of transistor 136 (e.g., capacitor 140 may be coupled across the gate and source terminals of p-type transistor 136). Capacitor 142 may have a first terminal coupled to the source terminal of transistor 136 and a second terminal coupled to ground line 190 (e.g., shunt capacitor 142 may be directly connected to the source terminal of p-type transistor 136). Current source 192 can be coupled between a positive power supply line 192 (e.g., a power supply terminal on which positive power supply voltage Vdd is provided) and the source terminal of transistor 136.

Transistor 136 being implemented as a p-type (p-channel) transistor in the example of FIG. 3 is exemplary. If the filter output terminal 112 is coupled to a gate of an n-type transistor (e.g., an n-channel metal-oxide-semiconductor or NMOS transistor), then transistor 136 should be implemented as a p-type transistor to help maintain adequate voltage headroom for filter circuitry 100. Alternatively, if the output terminal 112 is coupled to a gate terminal of a p-type transistor, then transistor 136 should be implemented as a n-type transistor to help maintain adequate voltage headroom for filter circuitry 100. Thus, the channel type for transistor 136 can be dependent on the type of transistor that is coupled to output terminal 112. The example of FIG. 3 in which transistor 136 is implemented as a MOS transistor is illustrative. In general, transistor 136 and/or other transistors (if included) within filter circuitry 100 can be implemented using metal-oxide-semiconductor field-effect transistors (MOSFETs), bipolar junction transistors (BJTs), insulated-gate bipolar transistors (IGBTs), junction field-effect transistors (JFETs), tunnel field-effect transistors (TFETs), fin field-effect transistors (FinFETs), silicon-on-insulator (SOI) transistors, carbon nanotube transistors, nanowire transistors, a combination of these transistors, and/or other types of transistors.

Configured in the arrangement of FIG. 3, transistor 136 would exhibit a transconductance gₘ that is a function of frequency. For instance, at low(er) frequencies, the transistor transconductance gₘ would bootstrap capacitor 140 and, as a result, transistor 136 and capacitors 140 and 142 would have no effect on signals arriving at output node 131. At high(er) frequencies, however, the transistor transconductance gₘ would be insufficient and, as a result, capacitor 140 would effectively short the gate and source terminals of transistor 136. In such scenarios, the loading at output node 131 would be a function of the capacitance of capacitors 132, 140, and 142. This results in a filter transfer function expressed as follows:

$$H ( s ) = \frac{Vout}{Vin} = \frac{\frac{s}{z} + 1}{{( \frac{s}{{ω}_{n}} )}^{2} + ( \frac{s}{Q {ω}_{n}} ) + 1} \qquad ( 1 )$$

$$where$$

$$z = \frac{{g}_{m}}{{C}_{140} + {C}_{142}} \qquad ( 2 )$$

$${ω}_{n} = \sqrt{\frac{{g}_{m}}{{R}_{130} ( {C}_{132} * {C}_{140} + {C}_{132} * {C}_{142} + {C}_{140} * {C}_{142} )}} \qquad ( 3 )$$

$$Q = \frac{\sqrt{( {C}_{132} * {C}_{140} + {C}_{132} * {C}_{142} + {C}_{140} * {C}_{142} )}}{{R}_{130} * {C}_{132} + \frac{{C}_{140} + {C}_{142}}{{g}_{m}}} * \sqrt{\frac{{R}_{130}}{{g}_{m}}} \qquad ( 4 )$$

and where C₁₃₂ represents the capacitance value of capacitor 132, C₁₄₀ represents the capacitance value of capacitor 140, C₁₄₂ represents the capacitance value of capacitor 142, and R₁₃₀ represents the resistance value of resistor 130. Q represents the quality factor of the filter; ωₙ represents a pole of the filter; and z represents a zero of the filter. The transfer function H(s) as expressed in equation 1 with variables defined in the associated equations 2 to 4 can provide the improved filter response 122 described in connection with FIG. 2. Moreover, any potential flicker noise contribution from transistor 132 can be rejected by a band-pass filter response provided at the source terminal of transistor 136.

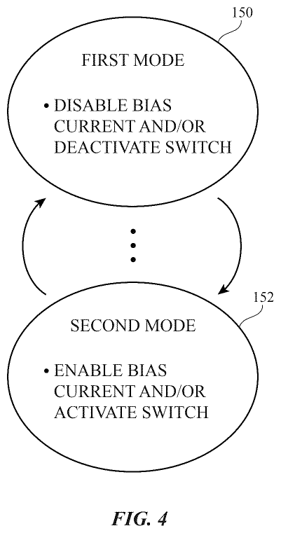

In accordance with some embodiments, low-pass filter circuitry 100 of the type shown in FIG. 3 can be operable in multiple modes (see, e.g., FIG. 4). As shown in FIG. 4, low-pass filter circuitry 100 can be configured in a first mode 150 and in a second mode 152. To configure filter circuitry 100 in the first mode 150, current source 138 (sometimes also referred to herein as a bias current) can be disabled and/or switch 134 can be deactivated. Doing so effectively deactivates (or switches out of use) a portion of low-pass filter circuitry 100 that includes transistor 136, capacitors 140 and 142, and bias current 138. Bias current 138 and/or switch 134 can be controlled by control circuit 144. Control circuit 144 can be part of processing circuitry that is included within the same integrated circuit on which filter circuitry 100 is formed (e.g., filter 100 and control circuit 144 can be formed on the same integrated circuit die) or can be part of processing circuitry that is included on a separate integrated circuit from that of filter circuitry 100 (e.g., filter 100 and control circuit 144 can be formed on separate integrated circuit chips). The first mode 150 can be used when filter circuitry 100 is operating in a first range of frequencies for when in-band droop can be tolerated.

Current source (bias current) 138 and switch 134 can be activated to configure filter circuitry 100 in the second mode 152. Doing so effectively activates (or switches into use) the portion of filter circuitry 100 that includes transistor 136, capacitors 140 and 142, and bias current 138. As described above, bias current 138 and/or switch 134 can be controlled by control circuit 144, sometimes referred to as a filter controller. The second mode 152 can be used when low-pass filter circuitry 100 is operating in a second range of frequencies, different than the first range of frequencies, when excessive in-band droop cannot be tolerated. The second range of frequencies may generally be greater than the first range of frequencies since severe in-band drooping typically occurs at higher frequencies. The first range of frequencies can include one or more first frequency bands (e.g., first radio-frequency bands), whereas the second range of frequencies can include one or more second frequency bands (e.g., second radio-frequency bands). The example of FIG. 4 in which filter circuitry 100 is operable between first mode 150 and second mode 152 is illustrative. In general, low-pass filter circuitry 100 can be operable in two or more modes, depending on the target frequency band of operation.

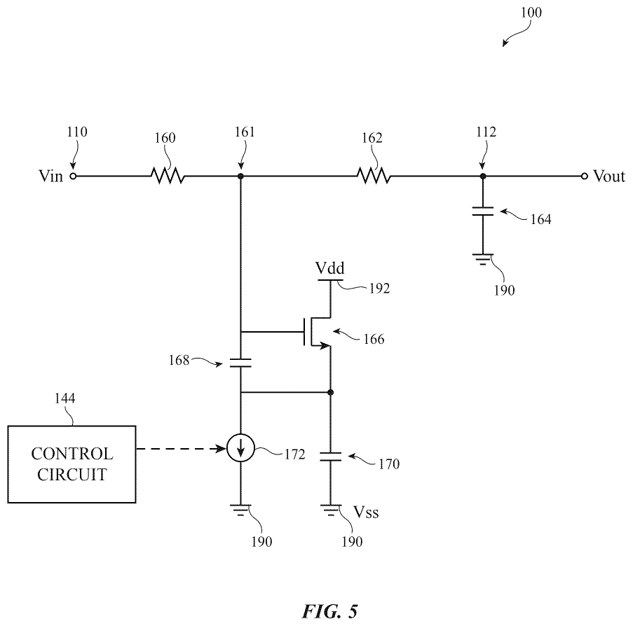

Low-pass filter circuitry 100 of the type shown in FIG. 3 in which transistor 136 has a gate terminal directly coupled (shorted) to the filter output terminal 112 is exemplary. FIG. 5 illustrates another embodiment of low-pass filter circuitry 100 having components coupled to a node separate from filter output node 112. As shown in FIG. 5, low-pass filter circuitry 100 may include resistors such as a first series resistor 160 and a second series resistor 162, a capacitor such as shunt capacitor 164, a transistor 166, capacitors 168 and 170, and a current source such as current source 172. Low-pass filter circuitry 100 can include only one active transistor such as transistor 166. Current source 172 is sometimes referred to as a current sink or a bias current. Resistor 160 may have a first terminal coupled to filter input terminal 110 and a second terminal coupled to node 161. Resistor 162 may have a first terminal coupled to node 161 and a second terminal coupled to filter output terminal 112. Shunt capacitor 164 may have a first terminal coupled to output terminal 112 and a second terminal coupled to ground line 190.

Transistor 166 may be an n-type transistor such as an n-channel metal-oxide-semiconductor (NMOS) transistor having a drain terminal coupled to positive power supply line 192 (e.g., a power supply terminal on which positive power supply voltage Vdd is provided), a gate terminal coupled (shorted) to node 161, and a source terminal. Capacitor 168 may have a first terminal coupled to the gate terminal of transistor 166 and a second terminal coupled to the source terminal of transistor 166 (e.g., capacitor 168 may be coupled across the gate and source terminals of transistor 166). Capacitor 170 may have a first terminal coupled to the source terminal of transistor 166 and a second terminal coupled to ground line 190 (e.g., shunt capacitor 170 may be directly connected to the source terminal of n-type transistor 166). Current sink 172 can be coupled between the source terminal of transistor 166 and ground line 190.

The example of FIG. 5 in which transistor 166 is implemented as a MOS transistor is illustrative. In general, transistor 166 and/or other transistors (if present) within filter circuitry 100 can be implemented using metal-oxide-semiconductor field-effect transistors (MOSFETs), bipolar junction transistors (BJTs), insulated-gate bipolar transistors (IGBTs), junction field- effect transistors (JFETs), tunnel field-effect transistors (TFETs), fin field-effect transistors (FinFETs), silicon-on-insulator (SOI) transistors, carbon nanotube transistors, nanowire transistors, a combination of these transistors, and/or other types of transistors.

Low-pass filter circuitry 100 of FIG. 5 can optionally be controlled by control circuit 144. Control circuit 144 can selectively activate and deactivate the bias current provided by current sink 172. Operated in this way, control circuit 144 can selectively activate and deactivate a portion of filter circuitry 100 that includes transistor 166, capacitors 168 and 170, and current sink 172. Control circuit 144 and filter circuitry 100 can be included as part of the same integrated circuit die or can be formed as part of different integrated circuit dies. Control circuit 144 can disable the bias current to operate filter circuitry 100 in a first filter mode and can enable the bias current to operate filter circuitry 100 in a second filter mode different than the first filter mode. The first filter mode can be used when filter circuitry 100 is operating in a first range of frequencies when in-band droop can be tolerated. The second filter mode can be employed when filter circuitry 100 is operating in a second range of frequencies when excessive in-band droop cannot be tolerated.

The second range of frequencies may generally be greater than the first range of frequencies since severe in-band drooping typically occurs at higher frequencies. The first range of frequencies can include one or more first frequency bands (e.g., first radio-frequency bands), whereas the second range of frequencies can include one or more second frequency bands (e.g., second radio-frequency bands). In general, low-pass filter circuitry 100 of FIG. 5 can be operable in two or more modes, depending on the target frequency band of operation. Filter circuitry 100 of the type shown in FIG. 5 is technically advantageous and beneficial for providing the improved low-pass filter response 122 of FIG. 2 with minimal increase in power consumption and circuit area.

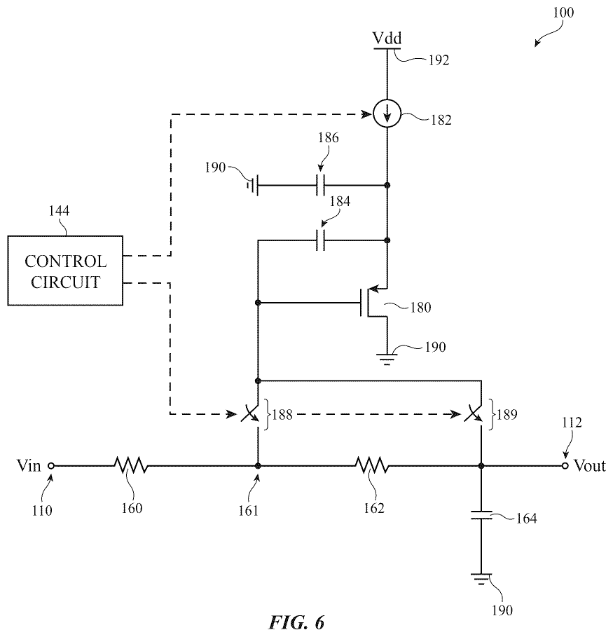

The example of FIG. 5 in which transistor 166 is an n-type transistor is illustrative. FIG. 6 is a circuit diagram showing another embodiment of filter circuitry 100 in which the portion of circuitry 100 that is coupled to node 161 includes a p-type transistor 180. As shown in FIG. 6, low-pass filter circuitry 100 may include resistors such as a first series resistor 160 and a second series resistor 162, a capacitor such as shunt capacitor 164, a p-type (e.g., PMOS) transistor 180, capacitors 184 and 186, and a current source such as current source 182. Current source 182 is sometimes referred to as a bias current. Resistor 160 may have a first terminal coupled to filter input terminal 110 and a second terminal coupled to node 161. Resistor 162 may have a first terminal coupled to node 161 and a second terminal coupled to filter output terminal 112. Shunt capacitor 164 may have a first terminal coupled to output terminal 112 and a second terminal coupled to ground line 190.

P-type transistor 180 may having a drain terminal coupled to ground line 190, a gate terminal selectively coupled to node 161 via switch 188 or to output terminal 112 via switch 189, and a source terminal coupled to current source 182. Capacitor 184 may have a first terminal coupled to the gate terminal of transistor 180 and a second terminal coupled to the source terminal of transistor 180 (e.g., capacitor 184 may be coupled across the gate and source terminals of transistor 180). Capacitor 186 may have a first terminal coupled to the source terminal of transistor 180 and a second terminal coupled to ground line 190 (e.g., shunt capacitor 186 may be directly connected to the source terminal of p-type transistor 180). Current source 182 can be coupled between positive power supply line 192 and the source terminal of transistor 180.

The example of FIG. 6 in which transistor 180 is implemented as a MOS transistor is illustrative. In general, transistor 180 and/or other transistors (if present) within filter circuitry 100 of FIG. 6 can be implemented using metal-oxide-semiconductor field-effect transistors (MOSFETs), bipolar junction transistors (BJTs), insulated-gate bipolar transistors (IGBTs), junction field-effect transistors (JFETs), tunnel field-effect transistors (TFETs), fin field-effect transistors (FinFETs), silicon-on-insulator (SOI) transistors, carbon nanotube transistors, nanowire transistors, a combination of these transistors, and/or other types of transistors.

Low-pass filter circuitry 100 of FIG. 6 can optionally be controlled by control circuit 144. Control circuit 144 can selectively activate and deactivate the bias current provided by current source 182 and can selectively activate and deactivate switches 188 and 189. At most one of switches 188 and 189 should be activated at any given point in time. In one mode, control circuit 144 can deactivate the portion of filter circuitry 100 that includes transistor 180 and capacitors 184 and 186 by disabling (deactivating) current source 182. Additionally or alternatively, control circuit 144 can deactivate the portion of filter circuitry 100 that includes transistor 180 and capacitors 184 and 186 by deactivating both switches 188. Switches 188 and 189 are sometimes referred to as filter switches.

In another mode, control circuitry can enable current source 182 while activating switch 188 without activating switch 189. When switch 188 is activated, filter circuitry 100 of FIG. 6 is structurally and functionally similar to the low-pass filter circuitry of FIG. 5, where the filter transistor (e.g., transistor 180) has its gate terminal coupled to node 161 between the series resistors except with a p-type channel implementation. In yet another mode, control circuitry can enable current source 182 while activating switch 189 without activating switch 188. When switch 189 is activated, filter circuitry 100 of FIG. 6 can be structurally and functionally identical to the low-pass filter circuitry of FIG. 3, where the filter transistor (e.g., transistor 180) has a gate terminal coupled to the filter output terminal 112.

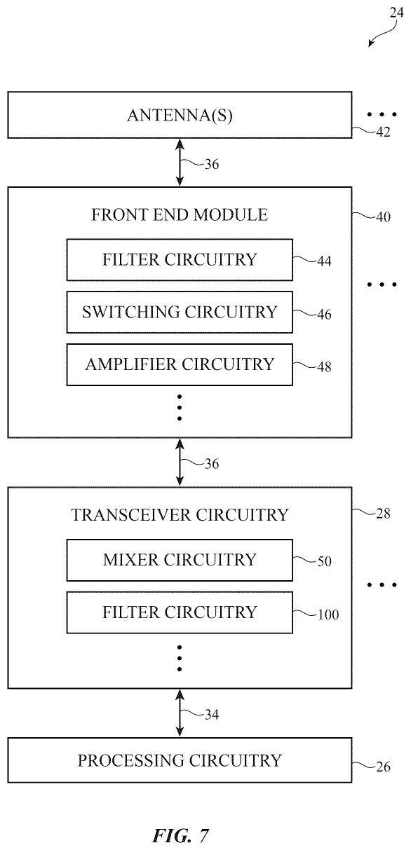

Filter circuitry 100 of the type described in connection with FIGS. 1-6 can be included as part of wireless circuitry in accordance with some embodiments. FIG. 7 is a block diagram of illustrative wireless circuitry 24 that can be provided with filter circuitry 100. Wireless circuitry 24 is sometimes referred to as wireless communications circuitry. As shown in FIG. 7, wireless circuitry 24 may include processing circuitry such as processing circuitry 26 (e.g., one or more processors), radio-frequency (RF) transceiver circuitry such as radio-frequency transceiver 28, radio-frequency front end circuitry such as radio-frequency front end module (FEM) 40, and antenna(s) 42. Processing circuitry 26 may include one or more baseband processor, application processor, digital signal processor, microcontroller, microprocessor, central processing unit (CPU), programmable device, a combination of these circuits, and/or other types of processing units. Processing circuitry 26 may be configured to generated digital (baseband) signals.

In the example of FIG. 7, wireless circuitry 24 is illustrated as including only a single processing unit 26, a single transceiver 28, a single front end module 40, and a single antenna 42 for the sake of clarity. In general, wireless circuitry 24 may include any desired number of processing units 26, any desired number of transceivers 28, any desired number of front end modules 40, and any desired number of antennas 42. Each processing unit 26 may be coupled to one or more transceivers 28 over respective baseband paths 34. Each transceiver 28 may include a transmitter circuit configured to output uplink signals to antenna 42, may include a receiver circuit configured to receive downlink signals from antenna 42, and may be coupled to one or more antennas 42 over respective radio-frequency transmission line paths 36. Each radio-frequency transmission line path 36 may have a respective front end module 40 disposed thereon. If desired, two or more front end modules 40 may be disposed on the same radio-frequency transmission line path 36. If desired, one or more of the radio-frequency transmission line paths 36 in wireless circuitry 24 may be implemented without any front end module.

Processing circuitry 26 may be coupled to transceiver 28 over baseband path 34. Transceiver 28 may be coupled to antenna 42 via radio-frequency transmission line path 36. Radio-frequency front end module 40 may be disposed on radio-frequency transmission line path 36 between transceiver 28 and antenna 42. Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is merely illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within an electronic device. Transmission lines in the electronic device may include coaxial cables, microstrip transmission lines, stripline transmission lines, edge-coupled microstrip transmission lines, edge-coupled stripline transmission lines, transmission lines formed from combinations of transmission lines of these types, etc. Transmission lines such as transmission lines in radio-frequency transmission line path 36 may be integrated into rigid and/or flexible printed circuit boards.

Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

Front end module (FEM) 40 may include radio-frequency front end circuitry that operates on the radio-frequency signals conveyed (transmitted and/or received) over radio-frequency transmission line path 36. Front end module 40 may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifiers and one or more low-noise amplifiers), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front end module components may be mounted to a common (shared) substrate such as a rigid printed circuit board substrate or flexible printed circuit substrate. If desired, the various front end module components may also be integrated into a single integrated circuit chip or on separate integrated circuit chips.

Filter circuitry 44, switching circuitry 46, amplifier circuitry 48, and other circuitry may be disposed on radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front end module 40. For example, transceiver 28 may be formed on another substrate such as the main logic board of an electronic device, a rigid printed circuit board, or flexible printed circuit that is not a part of front end module 40.

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio (NR) Frequency Range 1 (FR1) bands below 10 GHz, 5G New Radio Frequency Range 2 (FR2) bands between 20 and 60 GHz, etc.), 6G bands between 100-1000 GHZ (e.g., sub-THz, THz, or THF bands), etc.), other centimeter or millimeter wave frequency bands between 10-300 GHz (e.g., a short range wireless data transfer band that supports in-band full duplex communications such as a band between around 57 GHz and 64 GHz), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

In performing wireless transmission, processing circuitry 26 may provide baseband signals to transceiver 28 over baseband path 34. Transceiver 28 may further include circuitry for converting the baseband signals received from processing circuitry 26 into corresponding radio-frequency signals. For example, transceiver circuitry 28 may include mixer circuitry 50 for up-converting (or modulating) the baseband signals to intermediate frequencies or radio frequencies prior to transmission over antenna 42. Transceiver circuitry 28 may also include digital-to-analog converter (DAC) and/or analog-to-digital converter (ADC) circuitry for converting signals between digital and analog domains. Transceiver 28 may include a transmitter component to transmit the radio-frequency signals over antenna 42 via radio-frequency transmission line path 36 and front end module 40. Antenna 42 may transmit the radio-frequency signals to external wireless equipment by radiating the radio-frequency signals into free space.

In performing wireless reception, antenna 42 may receive radio-frequency signals from external wireless equipment. The received radio-frequency signals may be conveyed to transceiver 28 via radio-frequency transmission line path 36 and front end module 40. Transceiver 28 may include circuitry for converting the received radio-frequency signals into corresponding baseband signals. For example, transceiver 28 may use mixer circuitry 50 for down-converting (or demodulating) the received radio-frequency signals to intermediate frequencies or baseband frequencies prior to conveying the received signals to processing circuitry 26 over baseband path 34.

Transceiver 28 may further include a filter circuit such as low-pass filter circuitry 100 of the type described in connection with FIGS. 1-6. The example of FIG. 7 in which filter circuitry 100 is shown as being part of transceiver circuitry 28 is merely illustrative. If desired, other parts of wireless circuitry 24 can include low-pass filter circuitry 100. As an example not mutually exclusive with the other embodiments, one or more instances of filter circuitry 100 can be included as part of processing circuitry 26. As another example not mutually exclusive with the other embodiments, filter circuitry 100 can be included as part of front end module 40. Filter circuitry 100 need not be included as part of wireless circuitry 24. In general, filter circuitry 100 can be included as part of any electronic circuit that requires low-pass filtering.

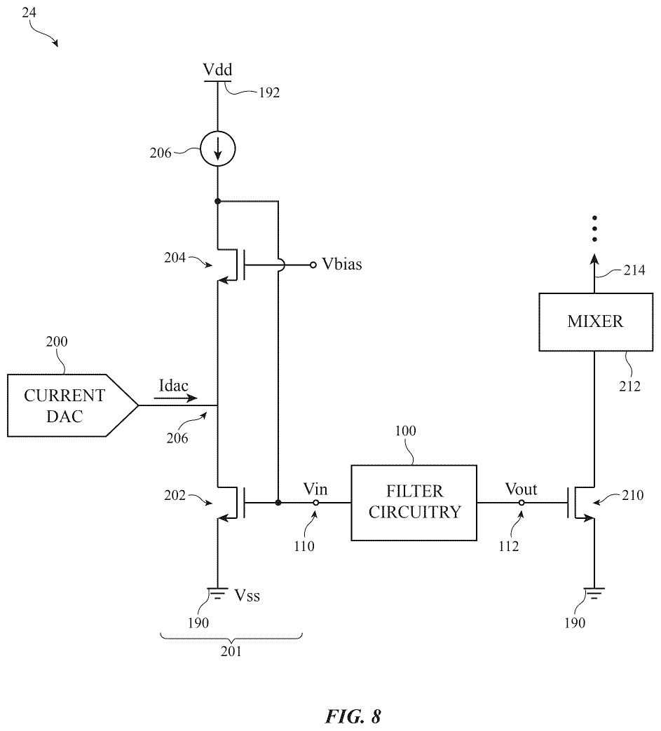

FIG. 8 is a circuit diagram showing how wireless circuitry 24 can include filter circuitry 100 coupled between a data converter and a mixer in accordance with some embodiments. As shown in FIG. 8, wireless circuitry 24 can include a data converter such as a digital-to-analog converter (DAC) 200, a current mirror circuit 201, a transistor such as transistor 210, and a mixer 212. Digital-to-analog converter 200 can be configured to output a current signal Idac and can thus sometimes referred to as a current DAC. Current DAC 200 can output current signal Idac to current mirror 201.

Current mirror 201 can include transistor 202, transistor 204, and current source 206 coupled together in series between ground (Vss) line 190 and positive power supply (Vdd) line 192. In particular, current source 206 may be coupled between Vdd line 192 and transistor 204. Transistor 204 (e.g., an NMOS transistor) can have a drain terminal coupled to current source 206, a gate terminal configured to receive a bias voltage Vbias, and a source terminal coupled to node 206. Node 206 may be coupled to the output of current DAC 200. Transistor 202 (e.g., an NMOS transistor) can have a drain terminal coupled to node 206, a source terminal coupled to Vss line 190, and a gate terminal coupled (shorted) to the drain terminal of transistor 204.

Low-pass filter circuitry 100 may have its input terminal 110 coupled to the gate terminal of transistor 202 within current mirror 201 and its output terminal 112 coupled to transistor 210. In particular, transistor 210 (e.g., an NMOS transistor) can have a gate terminal coupled to filter circuitry 100, a source terminal coupled to ground line 190, and a drain terminal coupled to mixer 212. Mixer 212 may represent a mixer component within mixer circuitry 50 of FIG. 7. Mixer 212 can be coupled to other downstream circuitry as indicated by connection 214.

The example of FIG. 8 in which low-pass filter circuitry 100 is coupled between a current mirror 201 and an n-type transistor 210 preceding a mixer 212 is illustrative. In other embodiments, filter circuitry 100 can have its input terminal 110 coupled to a gate terminal of a preceding p-type transistor and/or can have its output terminal 112 coupled to a gate terminal of a succeeding p-type transistor. In general, filter circuitry 100 can additionally or alternatively be incorporated into other parts of wireless circuitry 24. Filter circuitry 100 need not be included as part of wireless circuitry 24. In general, filter circuitry 100 can be included as part of any electronic circuit that requires low-pass filtering.

The foregoing is merely illustrative and various modifications can be made to the described embodiments. The foregoing embodiments may be implemented individually or in any combination.

What is claimed is:

1. Filter circuitry comprising:
a resistor having a first terminal coupled to an input of the filter circuitry and having a second terminal coupled to an output of the filter circuitry;
a first capacitor having a first terminal coupled to the second terminal of the resistor and having a second terminal coupled to a first power supply line; and
a transistor coupled to the first terminal of the resistor or the second terminal of the resistor.

2. The filter circuitry of claim 1, further comprising:
a switch coupled between the second terminal of the resistor and a gate terminal of the transistor.

3. The filter circuitry of claim 2, further comprising:
a second capacitor having a first terminal coupled to the gate terminal of the transistor and having a second terminal coupled to a source-drain terminal of the transistor.

4. The filter circuitry of claim 3, further comprising:
a third capacitor having a first terminal coupled to the source-drain terminal of the transistor and having a second terminal coupled to the first power supply line.

5. The filter circuitry of claim 4, further comprising:
a current source coupled between the source-drain terminal of the transistor and a second power supply line different than the first power supply line.

6. The filter circuitry of claim 5, wherein the current source is selectively deactivated when the filter circuitry is operating in a first range of frequencies and activated when the filter circuitry is operating in a second range of frequencies different than the first range of frequencies.

7. The filter circuitry of claim 1, further comprising:
an additional resistor having a first terminal coupled to the input of the filter circuitry and having a second terminal coupled to the first terminal of the resistor.

8. The filter circuitry of claim 7, wherein the transistor comprises a gate terminal coupled to the first terminal of the resistor and a first source-drain terminal coupled to a second power supply line different than the first power supply line.

9. The filter circuitry of claim 8, further comprising:
a second capacitor having a first terminal coupled to the gate terminal of the transistor and having a second terminal coupled to a second source-drain terminal of the transistor.

10. The filter circuitry of claim 9, further comprising:
a third capacitor having a first terminal coupled to the second source-drain terminal of the transistor and having a second terminal coupled to the first power supply line.

11. The filter circuitry of claim 10, further comprising:
a current source coupled between the second source-drain terminal of the transistor and the first power supply line.

12. The filter circuitry of claim 11, wherein the current source is selectively deactivated when the filter circuitry is operating in a first range of frequencies and activated when the filter circuitry is operating in a second range of frequencies different than the first range of frequencies.

13. The filter circuitry of claim 7, further comprising:
a first switch coupled between the first terminal of the resistor and a gate terminal of the transistor; and
a second switch coupled between the second terminal of the resistor and the gate terminal of the transistor.

14. Circuitry comprising:
a resistor having a first terminal coupled to an input terminal and having a second terminal coupled to an output terminal;
a first capacitor having a first terminal coupled to the second terminal of the resistor and having a second terminal coupled to a first power supply line; and
a transistor coupled to the second terminal of the resistor.

15. The circuitry of claim 14, wherein the output terminal is coupled to an additional transistor of a first channel type, and wherein the transistor has a second channel type different than the first channel type.

16. The circuitry of claim 14, further comprising:
a switch coupled between the second terminal of the resistor and a gate terminal of the transistor, wherein the circuitry is configured to provide a low-pass filter response with a first in-band droop when the switch is deactivated and a low-pass filter response with a second in-band droop, less than the first in-band droop, when the switch is activated.

17. The circuitry of claim 14, further comprising:
a second capacitor coupled between a gate terminal and a source-drain terminal of the transistor;
a third capacitor coupled between the source-drain terminal of the transistor and the first power supply line; and
a current source coupled between the source-drain terminal of the transistor and a second power supply line different than the first power supply line.

18. Circuitry comprising:
a first resistor having a first terminal coupled to an input terminal and having a second terminal;
a second resistor having a first terminal coupled to the second terminal of the first resistor and having a second terminal coupled to an output terminal;
a first capacitor having a first terminal coupled to the second terminal of the second resistor and having a second terminal coupled to a power supply line; and
a transistor coupled to a node disposed between the first and second resistors.

19. The circuitry of claim 18, further comprising:
a second capacitor coupled between a gate terminal and a source-drain terminal of the transistor;
a third capacitor coupled between the source-drain terminal of the transistor and the power supply line; and
a current sink coupled between the source-drain terminal of the transistor and the power supply line.

20. The circuitry of claim 19, wherein the circuitry is configured to provide a low-pass filter response with a first in-band droop when the current sink is deactivated and a low-pass filter response with a second in-band droop, less than the first in-band droop, when the current sink is activated.
